(19) United States
(12) Patent Application Publication
(10) Pub. No.: US 2012/0025239 A1
(43) Pub. Date: Feb. 2, 2012

(54) NANOCOMPOSITES AND LIGHT EMITTING DEVICE PACKAGE INCLUDING THE SAME

(75) Inventors: Jae Il KIM, Yongin (KR); Dong Hyun Cho, Suwon (KR); Suk Jin Ham, Seoul (KR)

(73) Assignee: SAMSUNG ELECTRO-MECHANICS CO., LTD.

(21) Appl. No.: 13/013,284

(22) Filed: Jan. 25, 2011

(30) Foreign Application Priority Data
Aug. 2, 2010 (KR) 10-2010-0074730

(51) Int. Cl. H01L 33/50; C08G 77/398; C08G 77/38; B82Y 20/00

(52) U.S. Cl. 257/98; 525/474; 525/477; 977/774; 257/E33.061

(57) ABSTRACT

Provided are nanocomposites and a light emitting device package including the same. The nanocomposites include nanoparticles, and silicon compounds bonded to surfaces of the nanoparticles and expressed by a specific chemical formula. The nanocomposites can be dispersed evenly in various matrices without the nanoparticles being agglutinated.

### CROSS-REFERENCE TO RELATED APPLICATIONS

This application claims the priority of Korean Patent Application No. 10-2010-0074730 filed on Aug. 2, 2010, in the Korean Intellectual Property Office, the disclosure of which is incorporated herein by reference.

### BACKGROUND OF THE INVENTION

1. Field of the Invention

The present invention relates to nanocomposites and a light emitting device package, and more particularly, to nanocomposites having a high degree of dispersibility, and a light emitting device package including the same.

2. Description of the Related Art

As for metallic nanoparticles, it is known that their properties are controllable by the size, shape, composition, degree of crystallinity, and structure thereof, as in the case of semiconductor nanoparticles, such as quantum dots. For this reason, metallic nanoparticles are usable in many fields of application including catalysts, electronics, optics, information storage, chemical and biological sensors and the like, and are thus undergoing extensive research.

In general, a method of preparing metallic nanoparticles may be roughly classified into gas phase synthesis and liquid phase synthesis. In the gas phase synthesis, metallic nanoparticles are synthesized at high voltage in a vacuum state. In the liquid phase synthesis, metallic nanoparticles are prepared by using a high-molecular or monomolecular surface active agent in an organic solvent. While the gas phase synthesis has limitations in terms of complicated synthesis equipment and low productivity and operability, the liquid phase synthesis is easy to perform and ensures high productivity and operability, thereby requiring relatively low costs and enabling mass production.

A representative example of the liquid phase synthesis for preparing metallic nanoparticles is polyol synthesis. Polyol synthesis allows for the production of colloidal particles of transition metals, including noble metals, and alloys thereof. Here, the noble metal may be, for example, gold (Au), silver (Ag), copper (Cu), platinum (Pt), palladium (Pd), nickel (Ni), cobalt (Co), iridium (Ir), osmium (Os), ruthenium (Ru), iron (Fe) or the like. According to the polyol synthesis, a metallic precursor undergoes reduction by the use of polyol at high temperature to thereby obtain metallic nanoparticles, and poly(vinyl pyrrolidone) is added thereto to coat the surface of the metallic nanoparticles with poly(vinyl pyrrolidone). Here, the poly(vinyl pyrrolidone) is added in order to prevent the agglutination of colloidal particles.

With regard to a metallic material such as Au, Ag, Pt and the like, the liquid phase synthesis is known to enable shape control, which allows the resultant nanoparticles to have various shapes in addition to spherical shapes, as well as size control thereof. In this respect, many studies involving property changes by shape have already been conducted.

In order to effectively utilize the above properties of metallic nanoparticles and to thereby expand their applicability, a functional group, which can be bonded to other organic molecules and biomolecules, needs to be introduced to the surfaces of metallic nanoparticles, so that the nanoparticles can be effectively dispersed in various matrices (matrixes).

### SUMMARY OF THE INVENTION

An aspect of the present invention provides nanocomposites having a high degree of dispersibility, and a light emitting device package including the same.

According to an aspect of the present invention, there is provided nanocomposites including: nanoparticles; and silicon compounds bonded to surfaces of the nanoparticles and expressed by chemical formula 1 below:

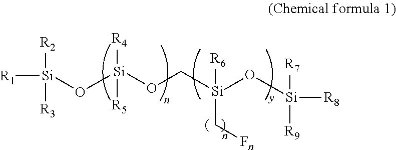

where each of R1, R2, R3, R6, R7, R8, and R9 is a methyl group or hydrogen, R4 and R5 are aromatic hydrocarbons, R6 is hydrogen, a methyl group or a phenyl group, Fₙ is NH₂, SH, COOH, CO(S)H, PPR₃, or P(O)PR₃, x and y are constants of between 1 and 100, and n is a constant of between 1 and 100.

The R1, R2, R3, R7, R8, and R9 may be methyl groups, respectively, the R4 and R5 may be benzyl groups, respectively, and R6 may be a methyl group.

The silicon compounds may have a molecular weight of between 200 and 50,000.

The nanoparticles may be at least one selected from the group consisting of silica, carbon black, metal powder, metal oxide, and quantum dots.

According to another aspect of the present invention, there is provided a light emitting device package including: a light emitting device mounted on a substrate; and a molding member covering the light emitting device and having nanocomposites dispersed therein, the nanocomposites including nanoparticles and silicon compounds bonded to surfaces of the nanoparticles and expressed by chemical formula 1 below:

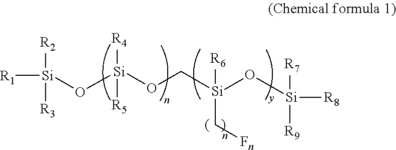

where each of R1, R2, R3, R6, R7, R8, and R9 is a methyl group or hydrogen, R4 and R5 are aromatic hydrocarbons, R6 is hydrogen, a methyl group or a phenyl group, Fₙ is NH₂, SH, COOH, CO(S)H, PPR₃, or P(O)PR₃, x and y are constants of between 1 and 100, and n is a constant of between 1 and 100.

The R1, R2, R3, R7, R8, and R9 may be methyl groups, respectively, the R4 and R5 may be benzyl groups, respectively, and R6 may be a methyl group.

The silicon compounds may have a molecular weight of between 200 and 50,000.

The nanoparticles may be quantum dots of at least one selected from the group consisting of CdSe/ZnS, ZnCdSe/ZnS, Si/SiO₂, Si nano-crystals, Cu-doped ZnS nano-crystals and ZnO.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a representational view illustrating nanocomposites according to an exemplary embodiment of the present invention;

FIG. 2 is a representational view illustrating how the nanocomposites of FIG. 1 are dispersed in a matrix;

FIG. 3 is a schematic cross-sectional view illustrating a light emitting device package according to an exemplary embodiment of the present invention; and

FIG. 4 is a graph showing the luminance characteristics of the light emitting device package depicted in FIG. 3.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and sizes of elements may be exaggerated for clarity. Like reference numerals in the drawings denote like elements.

According to an exemplary embodiment of the present invention, nanocomposites include nanoparticles and silicon compounds expressed by a specific chemical formula and bonded to the surfaces of the nanoparticles.

Since the silicon compounds are bonded to the surfaces of the nanoparticles in the nanocomposites according to this exemplary embodiment, the nanocomposites can be evenly dispersed in a variety of matrices without going through the agglutination of the nanoparticles.

The nanoparticles are not specifically limited, provided that they have a nanoscale particle size on average. For example, the nanoparticles, although not limited thereto, may be silica, carbon black, metal powder, metal oxide quantum dots or a mixture thereof.

Examples of the quantum dots may, for example, include CdSe/ZnS, ZnCdSe/ZnS, Si/SiO₂, Si nano-crystals, Cu-doped ZnS nano-crystals, ZnO nanoparticles, and the like.

The size of the nanoparticles, although not limited thereto, may fall within a range of between 1 nm and 100 nm.

In general, nanoparticles are susceptible to agglutination due to their particle size. In order to effectively utilize the properties of such nanoparticles, the nanoparticles need to be dispersed in various matrices. To this end, according to the related art, a method of modifying the surface of nanoparticles by using a silane coupling agent has been used.

However, this surface modification method using the silane coupling agent for nanoparticles is disadvantageous in that it is time-consuming and low in reproducibility.

According to preparation methods thereof, nanoparticles may be produced to have a negative (−) polarity or a positive (+) polarity on the surfaces thereof, or to have neutrally charged surfaces bonded to alkyl chains. Typically, nanoparticles are dispersed in limited kinds of matrices depending on the preparation method thereof. However, the surface modification of nanoparticles may allow for the dispersal thereof into various kinds of matrices.

According to this exemplary embodiment, a silicon compound, expressed by the following chemical formula 1, is bonded to the surface of the nanoparticles.

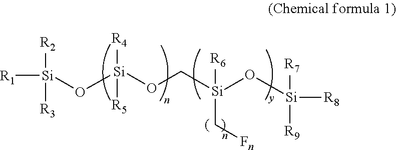

In chemical formula 1 above, each of R1, R2, R3, R6, R7, R8, and R9 is a methyl group or hydrogen, R4 and R5 are aromatic hydrocarbons, R6 is hydrogen, a methyl group or a phenyl group, Fₙ is NH₂, SH, COOH, CO(S)H, PPR₃, or P(O)PR₃, x and y are constants of between 1 and 100, and n is a constant of between 1 and 100.

The silicon compound has siloxane bonds (—Si—O—Si—) as the backbone thereof, and an electron-donating group (Fₙ) that can be bonded to the surfaces of nanoparticles.

In the above chemical formula, R1, R2, R3, R7, R8 and R9 may be methyl groups, R4 and R5 may be benzyl groups, and R6 may be a methyl group.

The electron-donating group (Fₙ) can be bonded to the surfaces of nanoparticles and serve to rapidly stabilize the nanoparticles when the silicon compound is mixed with the nanoparticles.

In the above chemical formula, ‘n’ may range from 1 to 100. By controlling an ‘n’ value according to the size of nanoparticles, the number of silicon compounds being bonded to the nanoparticle can be determined.

The ‘x’ and ‘y’ values may range from 1 to 100.

The silicon compounds may be oligomer or high-molecular compounds. The molecular weight of the silicon compounds may range from 200 to 50,000.

A high affinity with a variety of matrices is obtained by the siloxane bonds (—Si—O—Si—), forming the backbone of the silicon compound, and each substituent group thereof.

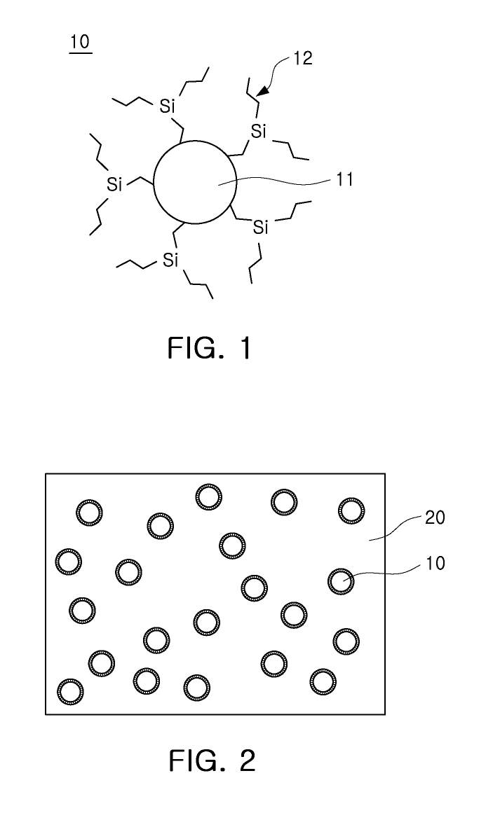

FIG. 1 is a representational view illustrating nanocomposites according to an exemplary embodiment of the present invention. FIG. 2 is a representational view illustrating how the nanocomposites of FIG. 1 are dispersed in a matrix.

Referring to FIG. 1, in nanocomposites 10 according to an exemplary embodiment of the present invention, a silicon compound 12 includes an electron-donating group (Fₙ) bonded to the surface of a nanoparticle 11, and the backbone of siloxane bonds is arranged in the direction of a matrix.

Accordingly, as shown in FIG. 2, nanoparticles are subjected to surface modification by the use of silicon compounds, and the nanocomposites 10 are dispersed evenly in a matrix 20 without the nanoparticles being agglutinated.

The matrix is not specifically limited, and may be an organic polymer, a polar organic solvent or the like. In more detail, the matrix may be an epoxy resin, a silicon resin, or Tetra Ethyl Ortho Silicate (TEOS).

By the use of the silicon compound expressed by a specific chemical formula, the nanocomposites, according to the exemplary embodiment of the invention, can ensure the rapid stabilization of the nanoparticles, and can be easily bonded to and dispersed in a variety of matrices without the nanoparticles being agglutinated.

According to an exemplary embodiment of the present invention, a light emitting device package includes a light emitting device mounted on a substrate; and a molding member covering the light emitting device and having nanocomposites dispersed therein, the nanocomposites including nanoparticles and silicon compounds expressed by a specific chemical formula and bonded to the surfaces of the nanoparticles.

The light emitting device, although not limited thereto, may be a light emitting diode (LED).

The nanocomposites may be nanocomposites described in the previous embodiment, and the components and effects thereof are as described above. The nanoparticles constituting the nanocomposites may be quantum dots. The quantum dots, although not limited thereto may be, for example, CdSe/ZnS, ZnCdSe/ZnS, Si/SiO2, Si nano-crystals, Cu-doped ZnS nano-crystals, ZnO nanoparticles, a mixture thereof, or the like.

The molding member, although not limited thereto, may be a silicon resin or an epoxy resin for example.

The nanocomposites ensure the rapid stabilization of the nanoparticles in the molding member and are easily bonded to the molding member so that the nanoparticles can be dispersed stably without being agglutinated.

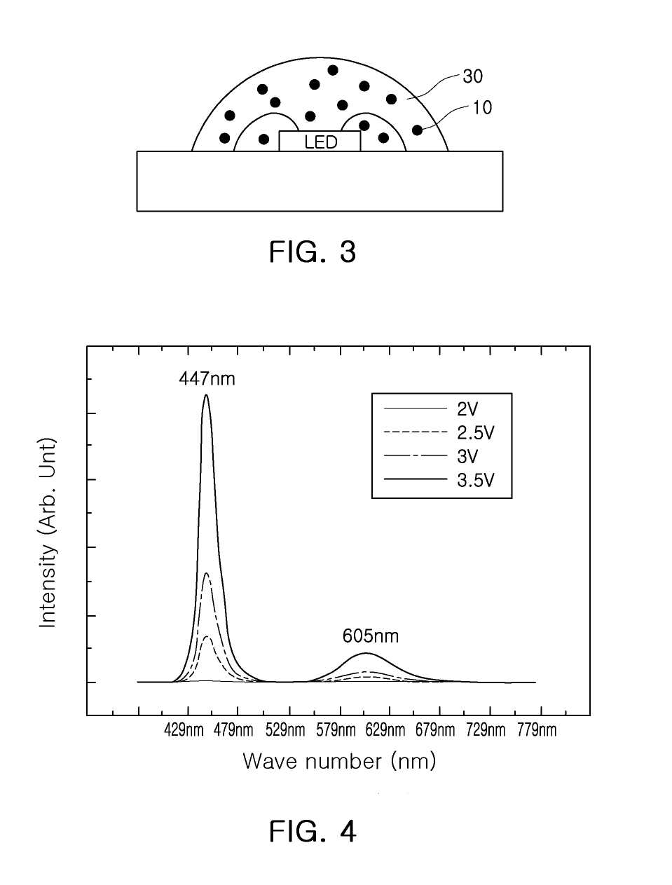

FIG. 3 is a schematic cross-sectional view illustrating a light emitting device package including nanocomposites, according to an exemplary embodiment of the present invention.

Referring to FIG. 3, a light emitting diode (LED) is mounted on a substrate, and the light emitting device is covered with a molding member 30.

As for the molding member 30, the nanocomposites 10 shown FIGS. 1 and 2 are dispersed therein.

The nanocomposites includes quantum dots of CdSe/ZnS and a silicon compound expressed by chemical formula 2 below:

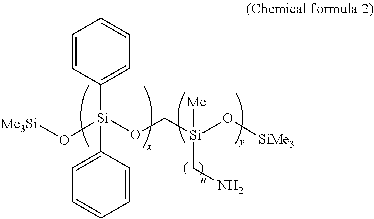

FIG. 4 is a graph showing the luminance characteristics of the light emitting device package of FIG. 3. Referring to FIG. 4, it can be seen that the luminance characteristics of the light emitting device package are constant even under different voltage conditions, due to a high degree of dispersibility of the nanocomposites with respect to the molding member 30.

As set forth above, according to exemplary embodiments of the invention, nanocomposites include nanoparticles and silicon compounds expressed by a specific chemical formula and bonded to the nanoparticles. ‘Fₙ’ of the silicon compounds denotes an electron-donating group that can bond to the surfaces of the nanoparticles, and allows the nanoparticles to be rapidly stabilized when being mixed with the silicon compounds. Furthermore, siloxane bonds (—Si—O—Si—) forming the backbone of the silicon compounds, and each substituent group provide a high affinity with a variety of matrices.

Furthermore, the nanocomposites can be dispersed evenly in a variety of matrices without going through the agglutination of the nanoparticles.

In addition, a light emitting device package including such nanocomposites can accomplish a constant luminance characteristic even under different voltage conditions.

While the present invention has been shown and described in connection with the exemplary embodiments, it will be apparent to those skilled in the art that modifications and variations can be made without departing from the spirit and scope of the invention as defined by the appended claims.

What is claimed is:

1. Nanocomposites comprising:
nanoparticles; and
silicon compounds bonded to surfaces of the nanoparticles and expressed by chemical formula 1 below: 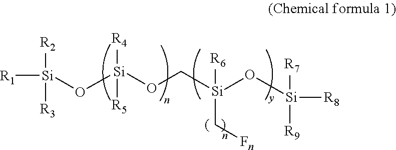
where each of R1, R2, R3, R6, R7, R8, and R9 is a methyl group or hydrogen,
R4 and R5 are aromatic hydrocarbons,
R6 is hydrogen, a methyl group or a phenyl group,
Fₙ is NH₂, SH, COOH, CO(S)H, PPR₃, or P(O)PR₃,
x and y are constants of between 1 and 100, and
n is a constant of between 1 and 100.

2. The nanoparticles of claim 1, wherein the R1, R2, R3, R7, R8, and R9 are methyl groups, respectively, the R4 and R5 are benzyl groups, respectively, and R6 is a methyl group.

3. The nanoparticles of claim 1, wherein the silicon compounds have a molecular weight of between 200 and 50,000.

4. The nanoparticles of claim 1, wherein the nanoparticles are at least one selected from the group consisting of silica, carbon black, metal powder, metal oxide, and quantum dots.

5. A light emitting device package comprising:
a light emitting device mounted on a substrate; and
a molding member covering the light emitting device and having nanocomposites dispersed therein, the nanocomposites comprising nanoparticles and silicon compounds bonded to surfaces of the nanoparticles and expressed by chemical formula 1 below: 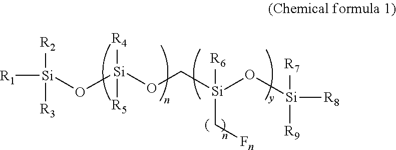
where each of R1, R2, R3, R6, R7, R8, and R9 is a methyl group or hydrogen,
R4 and R5 are aromatic hydrocarbons,
R6 is hydrogen, a methyl group or a phenyl group,
Fₙ is NH₂, SH, COOH, CO(S)H, PPR₃, or P(O)PR₃,
x and y are constants of between 1 and 100, and
n is a constant of between 1 and 100.

6. The light emitting device package of claim 5, wherein the R1, R2, R3, R7, R8, and R9 are methyl groups, respectively, the R4 and R5 are benzyl groups, respectively, and R6 is a methyl group.

7. The light emitting device package of claim 5, wherein the silicon compounds have a molecular weight of between 200 and 50,000.

8. The light emitting device package of claim 5, wherein the nanoparticles are quantum dots of at least one selected from the group consisting of CdSe/ZnS, ZnCdSe/ZnS, Si/SiO₂, Si nano-crystals, Cu-doped ZnS nano-crystals and ZnO.
